(19) United States
(12) Patent Application Publication
(10) Pub. No.: US 2025/0136765 A1
(43) Pub. Date: May 1, 2025

(54) POLYSILOXANE FORMULATION

(71) Applicant: Merck Patent GmbH, Darmstadt (DE)

(72) Inventors: Akira YAMASAKI, Kakegawa-shi (JP); Atsuko NOYA, Kakegawa-shi (JP)

(21) Appl. No.: 18/691,484

(22) PCT Filed: Sep. 12, 2022
(86) PCT No.: PCT/EP2022/075197

§ 371 Date: Mar. 13, 2024

(30) Foreign Application Priority Data
Sep. 15, 2021 (JP) 2021-150166

(51) Int. Cl. C08G 77/26; G03F 7/075

(52) U.S. Cl. CPC C08G 77/26; G03F 7/0758

(57) ABSTRACT

A cured film forming formulation comprising a polysiloxane having a specific structure, and a polymerization initiator. A method for manufacturing a cured film, which comprises applying the cured film forming formulation above a substrate to form a coating film, and heating the coating film.

### BACKGROUND OF THE INVENTION

### Technical Field

The present invention relates to a polysiloxane formulation. The present invention also relates to a method for manufacturing a cured film using the same, a cured film using the same, and a method for manufacturing a device comprising the cured film.

### Background Art

Polysiloxane is known for its high temperature resistance. When a cured film is formed from a formulation containing polysiloxane, a coating film is heated at a high temperature to rapidly proceed with the condensation reaction of the silanol group in polysiloxane and the reaction of the polymer having unsaturated bonds to cure the film. The cured film thus formed is used for electronic parts, semiconductor parts and the like.

For example, by means of using a photopolymerizable functional group as the functional group of polysiloxane, a cured film forming formulation having excellent tack and patterning properties has been proposed.

In recent years, a cured film formed using polysiloxane has been used also as a barrier wall for partitioning between pixels in display devices such as an organic electroluminescence element (OLED), a quantum dot display, and a thin film transistor array.

### PRIOR ART DOCUMENTS

### Patent Documents

[Patent Document 1] JP 2017-90515 A

### SUMMARY OF THE INVENTION

### Problems to be Solved by the Invention

The present inventors have found that there are still one or more following problems that need to be improved:
to provide a polysiloxane formulation capable of forming a thick cured film;
to provide a polysiloxane formulation capable of forming a cured film having excellent transmissivity;
to provide a polysiloxane formulation capable of forming a cured film having excellent heat resistance;
to provide a polysiloxane formulation capable of forming a cured film having a high aspect ratio and a high rectangularity; and
to provide a polysiloxane formulation capable of suppressing adhesion to a photomask.

### Means for Solving the Problems

The present invention provide a cured film forming formulation comprising:
(I) a polysiloxane Pab comprising a repeating unit represented by the formula (Ia) and a repeating unit represented by the formula (Ib), or
a mixture of a polysiloxane Pa comprising a repeating unit represented by the formula (Ia) and a polysiloxane Pb comprising a repeating unit represented by the formula (Ib):

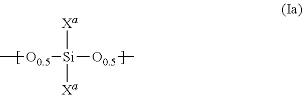

wherein,
X^{a} is each independently R^{Ia} or —O_{0.5}—, provided that at least one X^{a} is R^{Ia},
R^{Ia} is linear or branched C₁₋₆ alkylene that connects Si in the formula (Ia) with any N in the unit represented by the formula (Ia1):

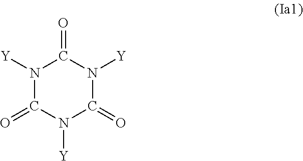

wherein,
Y is each independently a single bond, hydroxy, linear or branched C₁₋₁₀ alkyl, or linear or branched C₁₋₆ alkoxy, where C in the alkyl or alkoxy can be replaced with Si,

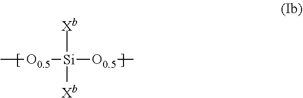

wherein,
X^{b} is each independently R^{Ib} or —O_{0.5}—, provided that at least one X^{b} is R^{Ib},
R^{Ib} is an organic group of C₃₋₁₀ having a meta(acryloyloxy) group; and
(II) a polymerization initiator.

The present invention provides a method for manufacturing a cured film, comprising applying the above-described formulation above a substrate to form a coating film, and heating the coating film

The present invention provides a cured film manufactured by the above-described method.

The present invention provides a method for manufacturing an electronic device comprising the above-described method for manufacturing a cured film.

### Effects of the Invention

The polysiloxane-containing formulation of the present invention provides, together with other embodiments of the present invention described herein, one or more following preferred effects:
a thick cured film can be formed;
a cured film having excellent transmissivity can be formed;
a cured film having excellent heat resistance can be formed;
a cured film having a high aspect ratio and a high rectangularity can be formed; and adhesion of polysiloxane formulation to a photomask can be suppressed.

### DETAILED DESCRIPTION OF THE INVENTION

### Mode for Carrying Out the Invention

### Definitions

Unless otherwise specified in the present specification, the definitions and examples described below are followed.

The singular form includes the plural form and “one” or “that” means “at least one”. An element of a concept can be expressed by a plurality of species, and when the amount (for example, mass % or mol %) is described, it means sum of the plurality of species.

“And/or” includes a combination of all elements and also includes single use of the element.

When a numerical range is indicated using “to” or “-”, it includes both endpoints and units thereof are common. For example, 5 to 25 mol % means 5 mol % or more and 25 mol % or less.

The descriptions such as “C_{x-y}”, “Cₓ-C_{y}” and “Cₓ” mean the number of carbons in a molecule or substituent. For example, C₁₋₆ alkyl means an alkyl chain having 1 or more and 6 or less carbons (methyl, ethyl, propyl, butyl, pentyl, hexyl etc.).

When polymer has plural types of repeating units, these repeating units copolymerize. These copolymerization can be any of alternating copolymerization, random copolymerization, block copolymerization, graft copolymerization, or a mixture thereof. When polymer or resin is represented by a structural formula, n, m or the like that is attached next to parentheses indicate the number of repetitions.

The alkyl means a group obtained by removing any one hydrogen from a linear or branched, saturated hydrocarbon and includes a linear alkyl and branched alkyl, and the cycloalkyl means a group obtained by removing one hydrogen from a saturated hydrocarbon comprising a cyclic structure and optionally includes a linear or branched alkyl in the cyclic structure as a side chain. The alkylene means a group obtained by removing any two hydrogens from a linear or branched, saturated hydrocarbon.

Celsius is used as the temperature unit. For example, 20 degrees means 20 degrees Celsius.

The additive refers to a compound itself having a function thereof (for example, in the case of a base generator, a compound itself that generates a base). An embodiment in which the compound is dissolved or dispersed in a solvent and added to a formulation is also possible. As one embodiment of the present invention, it is preferable that such a solvent is contained in the formulation according to the present invention as the solvent (III) or another component.

Hereinafter, embodiments of the present invention are described in detail.

### Cured Film Forming Formulation

The cured film forming formulation according to the present invention (hereinafter, sometimes referred to as the formulation) comprises (I) a polysiloxane and (II) a polymerization initiator.

The formulation according to the present invention can be a non-photosensitive formulation, a positive photosensitive formulation or a negative photosensitive formulation, but is preferably a negative photosensitive formulation. In the present invention, the negative photosensitive formulation means a formulation in which when the formulation is applied to form a coating film and exposed, the exposed area becomes insoluble in the alkaline developer, and the unexposed area is removed by the development to form a negative image.

### (I) Polysiloxane

The polysiloxane (I) used in the present invention (hereinafter, sometimes referred to as the component (I); the same applies to the other components) is as follows:
a polysiloxane Pab comprising a repeating unit represented by the formula (Ia) and a repeating unit represented by the formula (Ib), or
a mixture of a polysiloxane Pa comprising a repeating unit represented by the formula (Ia) and a polysiloxane Pb comprising a repeating unit represented by the formula (Ib).

Although not to be bound by theory, it is considered that since the component (I) comprises a repeating unit represented by the following formula (Ia) and a repeating unit represented by the following formula (Ib), shrinking or scattering of low molecular weight components during curing can be suppressed, and thickening of the cured film or a highly rectangular shape can be achieved.

The polysiloxane used in the present invention is not particularly restricted on its structure and can be freely selected in accordance with the aimed applications. According to the number of the oxygen atoms bonded to a silicon atom, the skeleton structure of a polysiloxane can be classified into a silicone skeleton (the number of oxygen atoms bonded to a silicon atom is 2), a silsesquioxane skeleton (the number of oxygen atoms bonded to a silicon atom is 3), and a silica skeleton (the number of oxygen atoms bonded to a silicon atom is 4). In the present invention, any of these can be used. The polysiloxane molecular can contain a plurality of combinations of any of these skeleton structures.

The formula (Ia) is as follows:

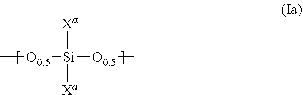

wherein,
X^{a} is each independently R^{Ia} or —O_{0.5}—, provided that at least one X^{a} is R¹.
R^{Ia} is linear or branched C₁₋₆ alkylene that connects Si in the formula (Ia) with any N in the unit represented by the formula (Ia1). R^{Ia} is preferably linear C₁₋₆ alkylene, more preferably methylene, ethylene and propylene. The formula (Ia1) is as follows:

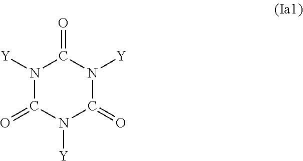

wherein,
Y is each independently a single bond, hydroxy, linear or branched C₁₋₁₀ alkyl, or linear or branched C₁₋₆ alkoxy, where C in the alkyl or alkoxy can be replaced with Si. Y is preferably a single bond, and when Y is a single bond, R^{Ia} in the formula (Ia) and N in the unit represented by the formula (Ia1) are connected.

The formula (Ib) is as follows:

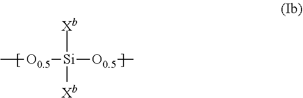

wherein,
X^{b} is each independently R^{Ib} or —O_{0.5}—, provided that at least one X^{b} is R^{Ib}, and preferably, just one of the two is R^{Ib}. R^{Ib} is an organic group of C₃₋₁₀ having a meta(acryloyloxy) group. The (meth)acryloyloxy group is a collective term for an acryloyloxy group and a methacryloyloxy group, and the carbon number of C₃₋₁₀ also includes a carbon atom contained in the (meth)-acryloyloxy group. Specific examples of R^{Ib} include 3-(meth)acryloyloxypropyl, 4-(meth)acryloyloxybutyl and 2-(meth)acryloyloxyethyl.

The content of the repeating unit represented by the formula (Ia) is preferably 8 to 30 mass %, more preferably 10 to 28 mass %, based on the total content of the component (I).

The content of the repeating unit represented by the formula (Ia1) is preferably 1 to 10 mass %, more preferably 1 to 8 mass %, based on the total content of the component (I).

The content of the repeating unit represented by the formula (Ib) is 3 to 35 mass %, more preferably 5 to 33 mass %, based on the total content of the component (I).

The content of the repeating unit represented by the formula (Ia) and the content of the repeating unit represented by the formula (Ib) are preferably 5:1 to 1:3, more preferably 4:1 to 1:3, in terms of mass ratio.

The component (I) is preferably a mixture of a polysiloxane Pa comprising a repeating unit represented by the formula (Ia) and a polysiloxane Pb comprising a repeating unit represented by the formula (Ib).

Preferably, the polysiloxane Pab, the polysiloxane Pa and/or the polysiloxane Pb further comprises a repeating unit represented by the formula (Ic):

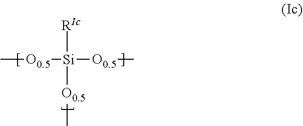

wherein,
R^{Ic} is hydrogen, a C₁₋₃₀, linear, branched or cyclic, saturated or unsaturated, aliphatic hydrocarbon group or aromatic hydrocarbon group, preferably hydrogen, C₁₋₆, linear, branched or cyclic alkyl, or C₆₋₁₀ aryl, more preferably hydrogen, methyl, ethyl or phenyl. The aliphatic hydrocarbon group and the aromatic hydrocarbon group are each unsubstituted or substituted with fluorine, hydroxy or C₁₋₈ alkoxy, and in the aliphatic hydrocarbon group and the aromatic hydrocarbon group, methylene (—CH₂—) is not replaced, or one or more methylene is replaced with —O— or —CO—, provided that R^{Ic} is neither hydroxy nor alkoxy, and R^{Ic} has no (meth)acryloyloxy group.

The number of the repeating unit represented by the formula (Ic) is preferably 1% or more, more preferably 20% or more, based on the total number of the repeating units contained in the polysiloxane molecule. When the formulating ratio of the repeating unit represented by the formula (Ia) is high, the electrical characteristics of the cured film are lowered, the adhesion of the cured film to the contact film is lowered, and the hardness of the cured film is reduced, so that the film surface is likely scratched. For that reason, the number of the repeating unit represented by the formula (Ia) is preferably 95% or less, more preferably 90% or less, based on the total number of the repeating units contained in the polysiloxane molecule.

The polysiloxane Pab, the polysiloxane Pa and/or the polysiloxane Pb can preferably further comprise a repeating unit represented by the formula (Id). Preferably, the polysiloxane Pb can preferably further comprise a repeating unit represented by the formula (Id).

The formula (Id) is as follows:

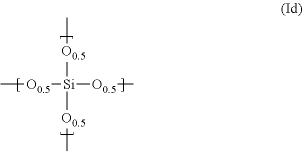

In the polysiloxane Pb, the number of the repeating unit represented by the formula (Id) is preferably 8% or more, more preferably 10 to 99%, further preferably 10 to 80%, based on the total number of the repeating units contained in the polysiloxane molecule. When the formulating ratio of the repeating unit represented by the formula (Id) is high, the compatibility with the solvent or the additive decreases and the film stress increases, so that cracks are likely to occur. When the above formulating ratio is low, hardness of the cured film decreases.

The polysiloxane used in the present invention can comprise repeating units other than the above, but the number of the repeating units other than the above is preferably 20% or less, more preferably 10% or less, based on the total number of the repeating units contained in the polysiloxane molecule. It is also a preferred embodiment of the present invention that no repeating unit other than the above is included.

The polysiloxane used in the present invention preferably has silanol at the end. Silanol means one in which an OH group is directly bonded to the Si skeleton of a polysiloxane, and it is one in which hydroxy is directly bonded to a silicon atom in a polysiloxane containing the above-mentioned repeating units or the like. That is, silanol is formed by binding —O_{0.5}H with —O_{0.5}— of the above formulae. The content of silanol in polysiloxane varies depending on the synthesis conditions, for example, formulating ratio of the monomers and type of the reaction catalyst. The content of this silanol can be evaluated by quantitative infrared absorption spectrum measurement. The absorption band assigned to silanol (SiOH) appears as an absorption band having a peak in the range of 900±100 cm⁻¹ of the infrared absorption spectrum. The higher the content of silanol, the higher the strength of this absorption zone.

The mass average molecular weight of the polysiloxane used in the present invention is preferably 500 to 30,000, and in terms of solubility in an organic solvent, coatability on a substrate, and solubility in an alkaline developer, is more preferably 500 to 25,000, further preferably 1,000 to 20,000. The mass average molecular weight is a mass average molecular weight in terms of polystyrene, which can be measured by gel permeation chromatography based on polystyrene.

The content of the component (I) is preferably 50 to 90 mass %, more preferably 55 to 85 mass %, based on the total mass of the formulation excluding the solvent.

### (II) Polymerization Initiator

The formulation according to the present invention comprises a polymerization initiator. The polymerization initiator includes a polymerization initiator that generates an acid, a base or a radical by radiation, and a polymerization initiator that generates an acid, a base or a radical by heat. In the present invention, the former is preferable and the photo radical generator is more preferable, in terms of process shortening and cost since the reaction is initiated immediately after the irradiation of radiation and the reheating process performed after the irradiation of radiation and before the development process can be eliminated.

The photo radical generator can improve the resolution by firming the shaped pattern or increasing the contrast of development. The photo radical generator used in the present invention is a photo radical generator that emits a radical when irradiated with radiation. Examples of the radiation include visible light, ultraviolet light, infrared light, X-ray, electron beam, α-ray, γ-ray, and the like.

Examples of the photo radical generator include azo-based, peroxide-based, acylphosphine oxide-based, alkylphenone-based, oxime ester-based, and titanocene-based initiators. Among them, alkylphenone-based, acylphosphine oxide-based and oxime ester-based initiators are preferred, and 2,2-dimethoxy-1,2-diphenylethan-1-one, 1-hydroxy-cyclohexylphenyl ketone, 2-hydroxy-2-methyl-1-phenylpropan-1-one, 1-[4-(2-hydroxyethoxy)phenyl]-2-hydroxy-2-methyl-1-propan-1-one, 2-hydroxy-1-{4-[4-(2-hydroxy-2-methylpropionyl)-benzyl]phenyl}-2-methylpropan-1-one, 2-methyl-1-(4-methylthiophenyl)-2-morpholinopropan-1-one, 2-benzyl-2-dimethylamino-1-(4-morpholinophenyl)-1-butanone, 2-(dimethylamino)-2-[(4-methylphenyl)methyl]-1-[4-(4-morpholinyl)-phenyl]-1-butanone, 2,4,6-trimethylbenzoyldiphenyl-phosphine oxide, bis(2,4,6-trimethylbenzoyl)-phenylphosphine oxide, 1,2-octanedione-1-[4-(phenylthio)-2-(O-benzoyloxime)], 1-[9-ethyl-6-(2-methylbenzoyl)-9H-carbazol-3-yl]ethanone-1-(0-acetyloxime) are included.

The content of the component (II) varies depending on the type of polymerization initiator, the amount generated, the required sensitivity, and the dissolution contrast between the exposed area and the unexposed area, but is preferably 0.001 to 30 mass %, more preferably 0.01 to 10 mass %, based on the total content of the component (I). When the component (II) is a photo radical generator, if the formulating amount thereof is less than 0.001 mass %, the dissolution contrast between the exposed area and the unexposed area is too low, and the addition effect sometimes cannot be obtained. On the other hand, when the formulating amount of the photo radical generator is more than 30 mass %, cracks occur in the formed coating film or coloring due to decomposition of the photo radical generator becomes remarkable, so that the colorless transparency of the coating film decreases. In addition, when the formulating amount is large, thermal decomposition causes deterioration of electrical insulating property of the cured product and gas release, which causes a problem in the subsequent process. Furthermore, resistance of the coating film to a photoresist stripper containing monoethanolamine or the like as a main ingredient is decreased.

### (III) Solvent

The formulation according to the present invention can comprise a solvent. The solvent is not particularly limited as long as it can uniformly dissolve or disperse the above-described components and other components to be added at need. Examples of the solvent that can be used in the present invention include ethylene glycol monoalkyl ethers, such as ethylene glycol monomethyl ether, ethylene glycol monoethyl ether, ethylene glycol monopropyl ether and ethylene glycol monobutyl ether; diethylene glycol dialkyl ethers, such as diethylene glycol dimethyl ether, diethylene glycol diethyl ether, diethylene glycol dipropyl ether and diethylene glycol dibutyl ether; ethylene glycol alkyl ether acetates, such as methyl cellosolve acetate and ethyl cellosolve acetate; propylene glycol monoalkyl ethers, such as propylene glycol monomethyl ether and propylene glycol monoethyl ether (PGME); propylene glycol alkyl ether acetates, such as propylene glycol monomethyl ether acetate (PGMEA), propylene glycol monoethyl ether acetate and propylene glycol monopropyl ether acetate; aromatic hydrocarbons, such as benzene, toluene and xylene; ketones, such as methyl ethyl ketone, acetone, methyl amyl ketone, methyl isobutyl ketone and cyclohexanone; alcohols, such as ethanol, propanol, butanol, hexanol, cyclohexanol, ethylene glycol, glycerin, 3-methoxybutanol and 1,3-butanediol; esters, such as ethyl lactate, butyl acetate, 3-methoxybutyl acetate, ethyl 3-ethoxypropionate, methyl 3-methoxy-propionate; and cyclic esters, such as γ-butyrolactone, or the like. Preferably, PGME, 3-methoxybutanol, 1,3-butanediol, PGMEA, ethyl lactate, butyl acetate and 3-methoxybutyl acetate are used. The solvent can be used alone or in combination of any two or more.

So as to improve workability depending on the coating method adopted, and in consideration of the penetrability of the solution into the fine trench and the film thickness required outside the trench, the solvent content of the formulation according to the present invention can be appropriately selected depending on the mass average molecular weight of the polysiloxane, and distribution and structure thereof. The content of the solvent is preferably 0 to 70 mass %, more preferably 2 to 60 mass %, based on the total mass of the formulation according to the present invention.

The formulation according to the present invention does not essentially require a solvent. It is also an embodiment of the present invention that the formulation according to the present invention contains no solvent (III).

### (IV) Compound Containing Two or More (Meth)Acryloyloxy Groups

The formulation according to the present invention can comprise a compound containing two or more (meth)acryloyloxy groups (hereinafter, sometimes referred to as the (meth)acryloyloxy group-containing compound). The (meth)acryloyloxy group is a collective term for an acryloyloxy group and a methacryloyloxy group. This compound is a compound that can react with polysiloxane or the like to form a crosslinked structure. In order to form a crosslinked structure, a compound containing two or more (meth)acryloyloxy groups, which are reactive groups, is required. By containing three or more (meth)acryloyloxy groups, a higher-order crosslinked structure can be formed.

As such a compound containing two or more (meth)acryloyloxy groups, esters obtained by reacting (a) a polyol compound having two or more hydroxyl groups and (p) two or more (meth)acrylic acids are preferably used. As the polyol compound (a), compounds which has saturated or unsaturated aliphatic hydrocarbon, aromatic hydrocarbon, heterocyclic hydrocarbon, primary, secondary or tertiary amine, ether and the like as basic skeleton, and has two or more hydroxyl groups as substituents are included. This polyol compound can contain other substituents, such as carboxyl group, carbonyl group, amino group, ether bond, thiol group and thioether bond, as long as the effect of the present invention is not impaired.

Preferred polyol compounds include alkyl polyols, aryl polyols, polyalkanolamines, cyanuric acid, dipentaerythritol and the like. When the polyol compound (α) has three or more hydroxyl groups, it is not necessary that all the hydroxyl groups have reacted with (meth)acrylic acid, and the polyol compound (α) can be partially esterified. That is, these esters can have unreacted hydroxyl groups.

Examples of such esters include tris(2-acryloyloxyethyl)isocyanurate, bis(2-acryloyloxyethyl)-isocyanurate, dipentaerythritol hexa(meth)acrylate, tripentaerythritol octa(meth)acrylate, pentaerythritol tetra(meth)acrylate, pentaerythritol triacrylate, pentaerythritol tetraacrylate, dipropylene glycol diacrylate, tripropylene glycol diacrylate, trimethylolpropane triacrylate, polytetramethylene glycol dimethacrylate, trimethylolpropane trimethacrylate, ditrimethylolpropane tetraacrylate, tricyclodecanedimethanol diacrylate, 1,9-nonanediol diacrylate, 1,6-hexanediol diacrylate, 1,10-decanediol diacrylate, and the like. Of these, tris(2-acryloxyethyl)-isocyanurate, pentaerythritol triacrylate, pentaerythritol tetraacrylate and dipentaerythritol hexaacrylate are preferred from the viewpoint of reactivity and number of crosslinkable groups. In addition, any two or more of these compounds can also be combined in order to adjust the shape of the formed pattern.

From the viewpoint of reactivity, such a compound is preferably a molecule that is relatively smaller than the alkali-soluble resin. For that reason, the molecular weight thereof is preferably 2,000 or less, more preferably 1,500 or less.

The content of this (meth)acryloyloxy group-containing compound is adjusted according to the polymer, the type of the (meth)acryloyloxy group-containing compound used, and the like, but from the viewpoint of compatibility with the resin, it is preferably 15 to 40 mass %, more preferably 17 to 30 mass %, based on the total mass of the component (I). When a developer of low concentration is used, it is preferably 20 to 200 mass %. These (meth)acryloyloxy group-containing compounds can be used alone or in combination of any two or more.

The formulation according to the present invention can be combined with further compounds as needed. The materials that can be combined are described below. In addition, the total amount of the components other than (I) to (IV) in the entire formulation is preferably 10 mass % or less, more preferably 5 mass % or less, based on the total mass of the formulation.

The formulation according to the present invention can optionally contain other additives. As such additives, a surfactant, an adhesion enhancer, an antifoaming agent, a heat-curing accelerator, and the like are included.

The surfactant is added for the purpose of improving coating properties, developability, and the like. Examples of the surfactant that can be used in the present invention include nonionic surfactants, anionic surfactants, and amphoteric surfactants.

Examples of the nonionic surfactant include, polyoxyethylene alkyl ethers, such as polyoxyethylene lauryl ether, polyoxyethylene oleyl ether and polyoxyethylene cetyl ether; polyoxyethylene fatty acid diester; polyoxyethylene fatty acid monoester; polyoxyethylene polyoxypropylene block polymer; acetylene alcohol; acetylene alcohol derivatives, such as polyethoxylate of acetylene alcohol; acetylene glycol; acetylene glycol derivatives, such as polyethoxylate of acetylene glycol; fluorine-containing surfactants, such as Fluorad (trade name, manufactured by 3M Japan Limited), Megaface (trade name, manufactured by DIC Corporation), Surflon (trade name, manufactured by AGC Inc.); or organosiloxane surfactants, such as KP341 (trade name, manufactured by Shin-Etsu Chemical Co., Ltd.). Examples of the above-described acetylene glycol include 3-methyl-1-butyne-3-ol, 3-methyl-1-pentyn-3-ol, 3,6-dimethyl-4-octyne-3,6-diol, 2,4,7,9-tetramethyl-5-decyne-4,7-diol, 3,5-dimethyl-1-hexyne-3-ol, 2,5-di-methyl-3-hexyne-2,5-diol, 2,5-di-methyl-2,5-hexanediol and the like.

Examples of the anionic surfactant include ammonium salt or organic amine salt of alkyl diphenyl ether disulfonic acid, ammonium salt or organic amine salt of alkyl diphenyl ether sulfonic acid, ammonium salt or organic amine salt of alkyl benzene sulfonic acid, ammonium salt or organic amine salt of polyoxyethylene alkyl ether sulfuric acid, ammonium salt or organic amine salt of alkyl sulfuric acid and the like.

Examples of the amphoteric surfactant include 2-alkyl-N-carboxymethyl-N-hydroxyethyl imidazolium betaine, lauric acid amide propyl hydroxysulfone betaine and the like.

These surfactants can be used alone or as a mixture of any two or more types, and the formulating amount thereof is normally 50 to 10,000 ppm, and preferably 100 to 8,000 ppm, based on the formulation according to the present invention.

The adhesion enhancer has an effect of preventing the pattern from being peeled off by the stress to be applied after baking when a cured film is formed using the formulation according to the present invention. As the adhesion enhancer, imidazoles and silane coupling agents are preferable, and as imidazoles, 2-hydroxybenzimidazole, 2-hydroxyethylbenzimidazole, benzimidazole, 2-hydroxyimidazole, imidazole, 2-mercaptoimidazole and 2-amino imidazole are preferable, and 2-hydroxybenzimidazole, benzimidazole, 2-hydroxy imidazole and imidazole are particularly preferably used.

Examples of the defoaming agent include alcohol (C₁₋₁₈), higher fatty acids such as oleic acid and stearic acid, higher fatty acid esters such as glycerin monolaurylate, polyethers such as polyethylene glycol (PEG) (Mn: 200 to 10,000) and polypropylene glycol (PPG) (Mn: 200 to 10,000), silicone compounds such as dimethyl silicone oil, alkyl-modified silicone oil and fluorosilicone oil, and the above-described organic siloxane-based surfactants. These can be used alone or in combination of a plurality of any of these, and the addition amount thereof is preferably 0.1 to 3 mass % based on the total mass of the component (I).

Examples of the heat-curing accelerator include a thermal base generator, a thermal acid generator, and the like. Usually, by including a heat-curing accelerator, the curing rate at the time of heating of the coating film can be increased.

The formulation according to the present invention can also be used as a formulation having photosensitivity by further containing a photobase generator, a photoacid generator and the like.

### Method for Manufacturing a Cured Film

The method for manufacturing a cured film according to the present invention comprises applying the formulation according to the present invention above a substrate to form a coating film, and heating the coating film. In the present invention, “above a substrate” includes a case where the formulation is directly applied on the substrate and a case where the formulation is applied above the substrate via one or more intermediate layers. The method of forming the cured film is described in process order as follows.

### (1) Application Process

The shape of the substrate is not particularly limited and can be freely selected depending on the purpose. However, the formulation according to the present invention is characterized in that it easily penetrates into narrow trenches and the like and can form a uniform cured film even inside the trenches, and therefore it can be applied on a substrate with trenches and holes having a high aspect ratio. Specifically, it can be applied on a substrate with at least one trench having a width of the deepest portion of 0.2 μm or less and an aspect ratio of 2 or more, and the like. The shape of the trench is not particularly limited, and the cross section can be any shape such as a rectangular shape, a forward tapered shape, a reverse tapered shape, and a curved surface shape. Both ends of the trench can be open or closed.

As a typical example of a substrate with at least one trench having a high aspect ratio, a substrate for an electronic device comprising a transistor device, a bit line, a capacitor, and the like is referred. In the production of such electronic devices, there is a case that a process of forming an insulating film between a transistor device and a bit line called PMD, between a transistor device and a capacitor, between a bit line and a capacitor or between a capacitor and a metal wiring or an insulating film called IMD between a plurality of metal wirings, or a process of filling isolation trenches is sometimes followed by a through-hole plating process of forming holes penetrating upward and downward through the material for filling a fine trench.

Application of the formulation can be conducted by any method. Specifically, it can be freely selected from dip coating, roll coating, bar coating, brush coating, spray coating, doctor coating, flow coating, spin coating, slit coating, and the like. As the substrate on which the formulation is applied, a suitable substrate such as a silicon substrate, a glass substrate, a resin film, and the like can be used. Various semiconductor devices and the like can also be formed on these substrates as needed. When the substrate is a film, gravure coating can also be utilized. If desired, a drying process can be separately provided after applying a film. If necessary, the applying process can be repeated once, or twice or more to make the film thickness of the coating film to be formed as desired one.

### (2) Pre-Baking Process

After forming the coating film by applying the formulation, the coating film can be also prebaked (preheating treatment) in order to dry the coating film and reduce the residual amount of the solvent in the coating film. The pre-baking process can be carried out at a temperature of generally 50 to 150° C., preferably 90 to 120° C., in the case of a hot plate, for 10 to 300 seconds, preferably 30 to 120 seconds and in the case of a clean oven, for 1 to 30 minutes.

### (3) Exposure Process

In the case where the used formulation is photosensitive, after forming a coating film, the coating film surface is then irradiated with light. As the light source to be used for the light irradiation, any one conventionally used for a pattern forming method can be used. As such a light source, a high-pressure mercury lamp, a low-pressure mercury lamp, a lamp such as metal halide and xenon, a laser diode, an LED, and the like can be included. As the irradiation light, ultraviolet ray such as g-line, h-line and i-line is usually used. Except ultrafine processing for semiconductors or the like, it is general to use light of 360 to 430 nm (high-pressure mercury lamp) for patterning of several μm to several dozen μm. Above all, in the case of liquid crystal display devices, light of 430 nm is often used. In such a case, as described above, it is advantageous to combine a sensitizing dye with the formulation according to the present invention. The energy of the irradiation light is generally 5 to 2,000 mJ/cm², preferably 10 to 1,000 mJ/cm², although it depends on the light source and the film thickness of the coating film. If the irradiation light energy is lower than 5 mJ/cm², sufficient resolution cannot be obtained in some cases. On the other hand, when the irradiation light energy is higher than 2,000 mJ/cm², the exposure becomes excess and halation sometimes occurs.

In order to irradiate light in a pattern shape, a general photomask can be used. Such a photomask can be freely selected from well-known ones. The environment at the time of irradiation is not particularly limited, but can generally be set as an ambient atmosphere (in the air) or nitrogen atmosphere. In the case of forming a film on the entire surface of the substrate, light irradiation can be performed over the entire surface of the substrate. In the present invention, the pattern film also includes such a case where a film is formed on the entire surface of the substrate.

### (4) Post Exposure Baking Process

After the exposure, to promote the reaction between the polymer in the film by the polymerization initiator, post exposure baking can be performed, as necessary. Different from the curing process (6) to be described later, this heating treatment is performed not to completely cure the coating film but to leave only a desired pattern on the substrate after development and to make other areas capable of being removed by development. Therefore, this is not essential in the present invention.

When the post exposure baking is performed, a hot plate, an oven, a furnace, and the like can be used. The heating temperature should not be excessively high because it is not desirable for the acid, base or radical in the exposed area, which is generated by light irradiation, to diffuse to the unexposed area. From such a viewpoint, the range of the heating temperature after exposure is preferably 40 to 150° C., and more preferably 60 to 120° C. Stepwise heating can be applied as needed to control the curing rate of the formulation. The atmosphere during the heating is not particularly limited, but can be selected from in an inert gas such as nitrogen, under a vacuum, under a reduced pressure, in an oxygen gas, and the like, for the purpose of controlling the curing rate of the formulation. The heating time is preferably above a certain level in order to maintain higher the uniformity of temperature history in the wafer surface and is preferably not excessively long in order to suppress diffusion of the generated acid, base or radical. From such a viewpoint, the heating time is preferably 20 seconds to 500 seconds, and more preferably 40 seconds to 300 seconds.

### (5) Developing Process

After post-exposure baking is optionally performed subsequent to the exposure, the coating film is developed. As the developer to be used at the time of development, any developer conventionally used for developing a photosensitive formulation can be used. Preferable examples of the developer include an alkali developer which is an aqueous solution of an alkaline compound such as tetraalkylammonium hydroxide, choline, alkali metal hydroxide, alkali metal metasilicate (hydrate), alkali metal phosphate (hydrate), ammonia, alkylamine, alkanolamine and heterocyclic amine, and a particularly preferable alkali developer is tetramethylammonium hydroxide (TMAH) aqueous solution, a potassium hydroxide aqueous solution, or a sodium hydroxide aqueous solution. In this alkali developer, a water-soluble organic solvent such as methanol and ethanol, or a surfactant can be further contained, if necessary. The developing method can also be freely selected from conventionally known methods. Specifically, methods such as dipping in a developer (dip), paddle, shower, slit, cap coat, spray, and the like can be included. After the development with a developer, by which a pattern can be obtained, it is preferable that rinsing with water is carried out.

### (6) Curing Process

In the case where the used formulation is non-photosensitive, the coating film obtained in the process (1) and/or (2), or in the case where it is photosensitive, the pattern film obtained in the process (5), is cured by heating. The same heating apparatus used for the above-described post-exposure baking can be used for the curing process. The heating temperature in the curing process is not particularly limited as long as it is a temperature at which curing of the coating film can be performed and can be freely determined. However, if the silanol group of the polysiloxane remains, the chemical resistance of the cured film sometimes becomes insufficient, or dielectric constant of the cured film sometimes becomes higher. From such a viewpoint, a relatively high temperature is generally selected as the heating temperature. In order to keep high residual film ratio after curing, the curing temperature is more preferably 350° C. or lower, and particularly preferably 250° C. or lower. On the other hand, in order to accelerate the curing reaction and obtain a sufficiently cured film, the curing temperature is preferably 70° C. or higher, more preferably 80° C. or higher, and particularly preferably 90° C. or higher. The heating time is not particularly limited, but is generally 10 minutes to 24 hours, and preferably 30 minutes to 3 hours. In addition, this heating time is a time from when the temperature of the pattern film reaches a desired heating temperature. Usually, it takes about several minutes to several hours for the pattern film to reach a desired temperature from the temperature before heating. The curing process is preferably carried out in an air atmosphere.

The cured film according to the present invention is one manufactured by the above method.

The film thickness of the cured film according to the present invention is not particularly limited, but is preferably 10 μm or more, more preferably 15 to 60 μm, and further preferably 20 to 50 μm.

According to the present invention, it is possible to form a cured film pattern that is a thick film, has a high aspect ratio, and is excellent in rectangularity. The formed pattern of cured film has little change in the pattern width over the entire pattern, and in particular, there is little change in the pattern bottom width and the pattern top width.

When the pattern width ratio is equal to (pattern bottom width−pattern top width)/(pattern bottom width)×100, the pattern width ratio is preferably less than 5%.

The cured film thus obtained has a high transmittance. Specifically, when the film thickness is 30 μm, the transmittance for light having a wavelength of 400 nm is preferably 95% or more, more preferably 96% or more.

The obtained cured film has high heat resistance. Even after storage at 150° C. for 1,000 hours, the rate of change in transmittance is lower than before storage.

The method for manufacturing a device according to the present invention comprises the above-described method for manufacturing a cured film. The cured film manufactured using the formulation according to the present invention has a high transmittance, is a thick film, has a high aspect ratio, and achieves a highly rectangular shape. It is suitably used as a barrier wall for partitioning between pixels in display devices. Since the thick film pattern can be obtained according to the present invention, it can be suitably used for a micro-LED, a quantum dot display or an organic electroluminescence device, which requires a thicker barrier wall material.

The present invention is explained more particularly below with reference to Examples and Comparative Examples, but the present invention is not limited by these Examples and Comparative Examples at all.

Mass average molecular weight (Mw) is measured by the gel permeation chromatography (GPC) based on polystyrene. GPC is measured using Alliance (trademark) e2695 type high-speed GPC system (Nihon Waters K.K.) and Super Multipore HZ-N type GPC column (Tosoh Corporation). The measurement is conducted using monodispersed polystyrene as a standard sample and cyclohexene as an eluent, under the measuring conditions of a flow rate of 0.6 ml/min and a column temperature of 40° C., and then Mw is calculated as a relative molecular weight to the standard sample.

### Synthesis Example 1: Polysiloxane Pa-1

In a 1 L three-neck flask equipped with a stirrer, a thermometer and a condenser, 8 g of a 35 mass % HCl aqueous solution, 400 g of PGMEA and 27 g of water are charged, and then, a mixed solution of 39.7 g of phenyltrimethoxysilane, 34.1 g of methyltrimethoxysilane, 30.8 g of tris-(3-trimethoxysilylpropyl)-isocyanurate and 0.3 g of trimethoxysilane is prepared. The mixed solution is dropped into the flask at 10° C. and stirred at the same temperature for 3 hours. Subsequently, 300 g of propyl acetate is added, and the mixture is separated by a separating funnel into an oil layer and an aqueous layer. To further remove the sodium remaining in the oil layer after separation, rinsing with 200 g of water is performed four times. It is confirmed that the pH of the waste liquid tank is 4 to 5. The solvent of the obtained organic layer is removed by concentrating under reduced pressure, and PGMEA is added to the concentrate to adjust the solid content of 30 mass %, for preparing a Polysiloxane Pa-1 solution. Mw of the obtained Polysiloxane Pa-1 is 12,600.

### Synthesis Example 2: Polysiloxane Pb-1

In a 2 L flask equipped with a stirrer, a thermometer and a condenser, 36.7 g of a 25 mass % tetramethylammonium hydroxide aqueous solution, 600 ml of IPA and 3.0 g of water are charged, and then, a mixed solution of 17 g of methyltrimethoxysilane, 29.7 g of phenyltrimethoxysilane, 7.6 g of tetramethoxysilane and 43.4 g of 3-(methacryloyloxy)propyltrimethoxysilane is prepared in a dropping funnel. The mixed solution is added dropwise at 40° C., stirred at the same temperature for 2 hours, and then neutralized by adding a 10% HCl aqueous solution. 400 ml of toluene and 600 ml of water are added to the neutralized solution to separate them into two layers, and the aqueous layer is removed. The resulting product is rinsed three times with 300 ml of water, and the obtained organic layer is concentrated under reduced pressure to remove the solvent, and PGMEA is added to the concentrate to adjust the solid content of 30 mass %, for obtaining a Polysiloxane Pb-1 solution. Mw of the obtained Polysiloxane Pb-1 is 2,050.

### Synthesis Example 3: Polysiloxane Pb-2

A 2 L flask equipped with a stirrer, a thermometer, and a condenser is charged with 36.7 g of a 25 mass % tetramethylammonium hydroxide aqueous solution, 600 ml of IPA and 3.0 g of water, and 96.0 g of 3-(methacryloyloxy)propyltrimethoxysilane is introduced into a dropping funnel. Dropwise addition is performed at 40° C., and the mixture is stirred at the same temperature for 2 hours and then neutralized by adding a 10% HCl aqueous solution. 400 ml of toluene and 600 ml of water are added to the neutralized solution to separate them into two layers, and the aqueous layer is removed. The resulting product is rinsed three times with 300 ml of water, and the obtained organic layer is concentrated under reduced pressure to remove the solvent, and PGMEA is added to the concentrate to adjust the solid content of 30 mass %, for obtaining a Polysiloxane Pb-2 solution. Mw of the obtained polysiloxane Pb-2 is 3,200.

### Synthesis Example 4: Polysiloxane A

In a 2 L flask equipped with a stirrer, a thermometer, and a condenser, 29.1 g of methyltrimethoxysilane, 0.6 g of phenyltrimethoxysilane, 0.4 g of tetramethoxysilane and 308 ml of PGME are charged and the mixture is cooled to 0.2° C. 96.6 g of a 37 mass % tetra-n-butylammonium hydroxide methanol solution is added dropwise into the flask from a dropping funnel, and the mixture is stirred for 2 hours. Thereafter, 500 ml of normal propyl acetate is added, and then the mixture is cooled again to 0.2° C. A 3% hydrochloric acid aqueous solution of 1.1 equivalence to TBAH is added, subsequently the mixture is stirred for 1 hour to neutralize. To the neutralized solution, 1,000 ml of normal propyl acetate and 250 ml of water are added. The reaction solution is separated into two layers, and the obtained organic layer is rinsed three times with 250 cc of water and then concentrated under reduced pressure to remove water and the solvent. PGMEA is added to the concentrate to adjust the solid content of 30 mass %, for obtaining a Polysiloxane A solution. Mw of the obtained polysiloxane A is 2,630.

### Preparation of Cured Film Forming Formulation

Formulations of Examples and Comparative Examples are prepared so that the composition excluding the solvent has the component and content shown in Tables 1-1 and 1-2 below. In the table, the numerical values of the compositions are mass % of each component based on the total mass of the formulation excluding the solvent. A mixed solvent of PGMEA/PGME (35 mass %/65 mass %) is used, and the content thereof is 50 mass % based on the total mass of the formulation.

TABLE 1-1

| | Example | | | | | | |
|---|---|---|---|---|---|---|---|
| | 1 | 2 | 3 | 4 | 5 | 6 | 7 |
| Polysiloxane Pa-1 | 33.2 | 37.3 | 48.5 | 49.7 | 47.4 | 47.4 | 33.2 |
| Polysiloxane Pb-1 | 49.7 | 29.0 | 24.3 | 16.6 | 35.5 | 35.5 | 33.1 |
| Polysiloxane Pb-2 | | 16.6 | 8.10 | | | | |
| Polysiloxane A | | | | 16.6 | | | 16.6 |
| Acrylic polymer A | | | | | | | |
| Acryloyloxy group- | | 16.6 | 18.6 | 16.6 | 16.6 | | 16.6 |
| containing compound | | | | | | | |
| A | | | | | | | |
| Acryloyloxy group- | 16.6 | | | | | 16.6 | |
| containing compound | | | | | | | |
| B | | | | | | | |
| Photo radical generator | 0.42 | 0.42 | 0.42 | 0.42 | 0.42 | 0.42 | 0.42 |
| A | | | | | | | |
| Surfactant A | 0.08 | 0.08 | 0.08 | 0.08 | 0.08 | 0.08 | 0.08 |
| Tack | A | A | A | A | A | A | A |
| Transmittance(%) | 97 | 97 | 97 | 97 | 97 | 97 | 97 |
| Heat resistance | A | A | A | A | A | A | A |
| Pattern shape | A | A | A | A | A | A | A |
| Film thickness(μm) | 20 | 25 | 25 | 20 | 25 | 25 | 20 |
| Aspect ratio | 10 | 5 | 5 | 5 | 5 | 10 | 5 |

TABLE 1-2

| | Example | | Comparative Example | | | |
|---|---|---|---|---|---|---|
| | 8 | 9 | 1 | 2 | 3 | 4 |
| Polysiloxane Pa-1 | 66.3 | 66.3 | | 82.9 | | 41.5 |
| Polysiloxane Pb-1 | 16.6 | | 82.9 | | | |
| Polysiloxane Pb-2 | | 16.6 | | | | |
| Polysiloxane A | | | | | | |
| Acrylic polymer A | | | | | 82.9 | 41.4 |
| Acryloyloxy group- | 16.6 | 16.6 | 16.6 | 16.6 | 16.6 | 16.6 |
| containing compound A | | | | | | |
| Acryloyloxy group- | | | | | | |
| containing compound B | | | | | | |
| Photo radical generator A | 0.42 | 0.42 | 0.42 | 0.42 | 0.42 | 0.42 |
| Surfactant A | 0.08 | 0.08 | 0.08 | 0.08 | 0.08 | 0.08 |
| Tack | A | A | B | A | B | B |
| Transmittance(%) | 97 | 97 | 97 | 97 | 95 | 95 |
| Heat resistance | A | A | A | A | C | B |
| Pattern shape | A | A | C | C | B | B |
| Film thickness(μm) | 25 | 41 | 10 | 30 | 40 | 25 |
| Aspect ratio | 5 | 6 | 5 | 10 | 10 | 5 |

In the tables:
acrylic polymer A: “AZ HT-035C50” (Merck Electronics Co., Ltd.);
acryloyloxy group-containing compound A: tris-(2-acryloxyethyl)isocyanurate, “A-9300”, Shin-Nakamura Chemical Co., Ltd.;
acryloyloxy group-containing compound B:
pentaerythritol tri- and tetra-acrylate, “A-TMM-3”, Shin-Nakamura Chemical Co., Ltd.;
photo radical generator A: “ADEKA ARKLS NCI-930”, ADEKA Corporation; and
surfactant A: “KF-53”, Shin-Etsu Chemical Co., Ltd.

### (Tack Evaluation)

Each of the obtained formulations is applied on a glass substrate using a spin coater (1HDX2, manufactured by Mikasa Co., Ltd.). The coated substrate is subjected to prebaking for 90 seconds on a hot plate heated to 100° C. Using an aligner PLA-501 (Cannon Inc.), exposure is performed with the optimum integrated light amount for each through a mask engraved with a 20 μm line and space pattern (soft contact exposure), and the mask is removed immediately after exposure. The condition when the mask is removed is evaluated according to the following criteria. The results obtained are shown in Tables 1-1 and 1-2.
A: When the mask is vertically lifted, the mask is peeled off from the coating film without resistance.
B: When the mask is vertically lifted, the mask is not peeled off from the coating film.

### (Transmittance)

Each of the obtained formulations is applied on a non-alkali glass using a spin coater, and after the application, the coated one is subjected to prebaking at 100° C. for 90 seconds on a hot plate. The entire surface of the coated surface is exposed at 50 mJ/cm² using an i-line aligner, immersed in a 2.38 mass % TMAH aqueous solution for 60 seconds, and rinsed with pure water for 30 seconds. Subsequently, it is heated at 200° C. for 1 hour to cure. The obtained cured film is adjusted to be 30 μm. The obtained cured film is measured with a UV absorption measuring apparatus (U-4000), and the transmittance at a wavelength of 400 nm is determined. The obtained transmittance is shown in Tables 1-1 and 1-2.

### (Heat Resistance)

After the above-described transmittance measurement, the substrate is stored at 150° C. for 1,000 hours, and the transmittance is measured again. The rate of change in transmittance before and after storage is calculated, and it is evaluated according to the following criteria. The obtained results are shown in Tables 1-1 and 1-2.
A: The rate of change in transmittance is less than 1%.
B: The rate of change in transmittance is 1% or more and less than 5%.
C: The rate of change in permeability is 5% or more.

### (Pattern Shape)

Each of the obtained formulations is applied on a silicon wafer by spin coating, and after application, the coated one is heated (prebaked) at 100° C. for 90 seconds on a hot plate to form a coating film. Exposure is performed through a mask at 50 mJ/cm² using an i-line aligner, and the coating film is immersed in a 2.38 mass % TMAH aqueous solution for 60 seconds and then rinsed with pure water for 30 seconds and dried. As a result, a 10 μm contact hole (C/H) pattern is formed. This pattern is heated on a hot plate at 200° C. for 60 minutes to form a cured pattern.

At this time, the cross section is observed by SEM, the pattern bottom width and the pattern top width are measured, and the pattern width ratio is calculated from the formula: (pattern bottom width−pattern top width)/(pattern bottom width)×100. The pattern width ratio is evaluated according to the following criteria. The obtained results are shown in Tables 1-1 and 1-2.
A: The pattern width ratio is less than 5%.
B: The pattern width ratio is 5% or more and less than 20%.
C: The pattern width ratio is 20% or more and less than 50%.

### (Film Thickness)

The pattern formed in the above-described pattern shape is heated on a hot plate at 230° C. for 30 minutes, the film thickness (distance between the pattern bottom and the pattern top) is measured by observing the cross section, and the obtained results are shown in Tables 1-1 and 1-2.

### (Aspect Ratio)

For the pattern formed in the above-described pattern shape, by observing the cross section, the aspect ratio is calculated from the formula: film thickness/pattern bottom width, and the obtained results are shown in Tables 1-1 and 1-2.

1.-16. (canceled)

17. A cured film forming formulation comprising:
(I) a polysiloxane Pab comprising a repeating unit represented by the formula (Ia) and a repeating unit represented by the formula (Ib), or
a mixture of a polysiloxane Pa comprising a repeating unit represented by the formula (Ia) and a polysiloxane Pb comprising a repeating unit represented by the formula (Ib): 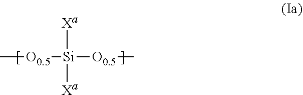
wherein,
X^{a} is each independently R^{Ia} or —O_{0.5}—, provided that at least one X^{a} is R^{Ia},
R^{Ia} is linear or branched C₁₋₆ alkylene that connects Si in the formula (Ia) with any N in the unit represented by the formula (Ia1): 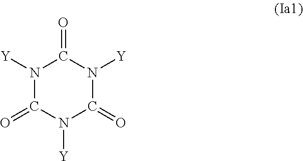
wherein,
Y is each independently a single bond, hydroxy, linear or branched C₁₋₁₀ alkyl, or linear or branched C₁₋₆ alkoxy, where C in the alkyl or alkoxy can be replaced with Si, 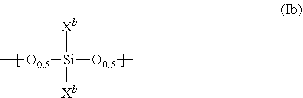
wherein,
X^{b} is each independently R^{Ib} or —O_{0.5}—, provided that at least one X^{b} is R^{Ib},
R^{Ib} is an organic group of C₃-10 having a meta(acryloyloxy) group; and
(II) a polymerization initiator.

18. The formulation according to claim 17, wherein the component (I) is a mixture of a polysiloxane Pa comprising a repeating unit represented by the formula (Ia) and a polysiloxane Pb comprising a repeating unit represented by the formula (Ib).

19. The formulation according to claim 18, wherein the polysiloxane Pa and/or the polysiloxane Pb further comprises a repeating unit represented by the formula (Ic): 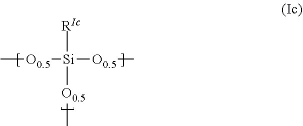
wherein,
R^{Ic} is hydrogen, a C₁₋₃₀, linear, branched or cyclic, saturated or unsaturated, aliphatic hydrocarbon group or aromatic hydrocarbon group,
the aliphatic hydrocarbon group and the aromatic hydrocarbon group are each unsubstituted or substituted with fluorine, hydroxy or C₁₋₈ alkoxy, and in the aliphatic hydrocarbon group and the aromatic hydrocarbon group, methylene is not replaced, or one or more methylene is replaced with —O— or —CO—, provided that R^{Ic} is neither hydroxy nor alkoxy.

20. The formulation according to claim 17, wherein the content of the repeating unit represented by the formula (Ib) is 3 to 35 mass % based on the total content of the component (I).

21. The formulation according to claim 17, wherein the content of the repeating unit represented by the formula (Ia) is 8 to 30 mass % based on the total content of the component (I).

22. The formulation according to claim 17, wherein the content of the unit represented by the formula (Ia1) is 1 to 10 mass % based on the total content of the component (I).

23. The formulation according to claim 17, wherein the content of the repeating unit represented by the formula (Ia) and the content of the repeating unit represented by the formula (Ib) are 5:1 to 1:3 in terms of mass ratio.

24. The formulation according to claim 17, wherein the polymerization initiator (II) is a photo radical generator.

25. The formulation according to claim 17, further comprising (III) a solvent.

26. The formulation according to claim 17, further comprising (IV) a compound containing two or more (meth)acryloyloxy groups.

27. The formulation according to claim 17, which is a negative photosensitive formulation.

28. A method for manufacturing a cured film, comprising applying the formulation according to claim 17 above a substrate to form a coating film, and heating the coating film.

29. A cured film manufactured by the method according to claim 28.

30. The cured film according to claim 29, which has a film thickness of 10 m or more.

31. The cured film according to claim 29, which has a light transmittance of 95% or more at 400 nm.

32. A device comprising the cured film according to claim 29.
